(19) United States
(12) Patent Application Publication
(10) Pub. No.: US 2002/0090771 A1
(43) Pub. Date: Jul. 11, 2002

(54) Self-align offset gate structure and method of manufacture

(76) Inventor: Yung-Chang Lin, Taichung Hsien (TW)

Correspondence Address: J.C. Patents, Suite 250, 4 Venture, Irvine, CA, 92618, US

(21) Appl. No.: 10/098,842

(22) Filed: Mar. 13, 2002

Related U.S. Application Data
(62) Division of application No. 09/716,306, filed on Nov. 20, 2000.

(30) Foreign Application Priority Data
Oct. 26, 2000 (TW) 89122538

(51) Int. Cl. H01L 29/76; H01L 21/00

(52) U.S. Cl. 438/163; 257/336; 257/344; 257/408

(57) ABSTRACT

A self-align offset gate structure and its method of manufacture. The method includes forming a damascene mask over a substrate and then forming gate openings over the damascene mask. Offset spacers are formed on the sidewalls of the gate openings and then sequentially forming a gate oxide layer and a conductive layer inside the gate opening. Chemical-mechanical polishing method is used to remove the conductive layer above the damascene mask surface. An ion implant is carried out implanting n-type ions or p-type ions into the conductive gate to form n-type or p-type gate respectively. The damascene mask is removed and then a lightly doped ion implant is conducted to form lightly doped source/drain regions. Finally, spacers are formed on the sidewalls of the gates and the offset spacers and then a heavily doped ion implant is carried out to form the heavily doped source/drain regions.

### CROSS-REFERENCE TO RELATED APPLICATION

This application claims the priority benefit of Taiwan application serial no. 89122538, filed Oct. 26, 2000.

### BACKGROUND OF THE INVENTION

1. Field of Invention

The present invention relates to a semiconductor device structure and its method of manufacture. More particularly, the present invention relates to a self-aligned offset gate structure and its method of manufacture.

2. Description of Related Art

The conventional method of manufacturing the source/drain terminal of a transistor on a substrate includes using the gate as a mask to carry out lightly doped ion implant, thereby forming a lightly doped source/drain region. Thereafter, spacers are formed on the sidewalls of the gate and then a heavily doped ion implant is carried out using the gate and the spacers as a mask. Finally, the substrate is annealed to form heavily doped source/drain regions. However, during the annealing operation, a portion of the dopants may diffuse into the bottom section of the gate so that parasitic capacitors are created between the gate and the source/drain terminals. Following the rapid increase in the level of integration of semiconductor devices, design rules for forming the miniature device have to be reduced correspondingly. As design rules are tightened, dopant diffusion is more problematic because of possible intensification of the short channel effect. FIGS. 1 through 5 are schematic cross-sectional views showing the progression of steps for manufacturing the gate and source/drain terminals of a conventional transistor. As shown in FIG. 1, a substrate 101 having an isolation structure 102 is provided. A gate oxide layer 104 is formed over the substrate 101 and then a conductive layer 103 is deposited over the gate oxide layer 104.

As shown in FIG. 2, a first patterned photoresist layer (not shown) is formed over the conductive layer 103. An n-type ion implant is carried out using the first patterned photoresist layer as a mask to form an n-type conductive layer 113. The first photoresist layer is removed. A second patterned photoresist layer (not shown) is formed over the n-type conductive layer 113. A p-type ion implant is carried out using the photoresist layer as a mask to form a p-type conductive layer 123. The second photoresist layer is removed.

A third patterned photoresist layer (not shown) is formed over the n-type conductive layer 113 and the p-type conductive layer 123 as shown in FIG. 3. Using the third photoresist layer as a mask, the conductive layers 113 and 123 are etched to form an n-type gate 114 and a p-type gate 124 respectively. The third photoresist layer is removed. An ion implant is next carried out implanting a low dose of n-type and p-type dopants into the substrate 101 on each side of the n-type gate 114 and the p-type gate 124. Ultimately, lightly doped source/drain regions 106 and 108 are formed in the substrate 101.

As shown in FIG. 4, a conformal silicon nitride layer is formed over the n-type gate 114, the p-type gate 124 and the lightly doped source/drain regions 106 and 108. An etching is conducted to remove the silicon nitride layer over the n-type gate 114, the p-type gate 124 and the lightly doped source/drain region 106 and 108. Hence, silicon nitride spacers 105 are formed on the sidewalls of the n-type gate 114 and the p-type gate 124. Thereafter, depending on design, additional steps may be required to form a heavily doped source/drain region 116 and 118 in the substrate 101 on each side of the spacers 105.

During annealing, a portion of the dopants in the substrate 101 may diffuse into the region under the gates 114 and 124 so that parasitic capacitance is created between the gate and the source/drain terminal.

To reduce the parasitic capacitance due to annealing, offset spacers 107 are often formed on the sidewalls of the gate 114 and 124 before forming the lightly doped source/drain regions 106 and 108 as shown in FIG. 5. In subsequent annealing step, dopants inside the source/drain region is prevented from moving into the region under the n-type gate 114 and the p-type gate 124, thereby reducing parasitic capacitance.

In the above method, the gate is formed by photolithographic and etching processes. Typically, if a yellow light etching photolithographic station is used, there is a limitation on the minimal line width of the gate. Otherwise, the station needs to be changed. Although the formation of an extra offset spacer on the sidewalls of the gate can effectively lower parasitic capacitance, overall width of the gate is increased leading to area waste. Thus, the level of integration is constrained. Furthermore, in the fabrication of CMOS gate, gate profile change may occur due to a difference in etching ratio between the differently doped gates.

### SUMMARY OF THE INVENTION

Accordingly, one object of the present invention is to provide a self-align offset gate structure and its method of manufacture. The method includes the following steps. First, a damascene mask is formed over a substrate and then gate openings are formed in the damascene mask. Offset spacers are formed on the sidewalls of the gate openings. A gate oxide layer and a conductive layer are sequentially formed inside the gate opening. Chemical-mechanical polishing method is used to remove the conductive layer above the damascene mask surface. An ion implant is carried out implanting n-type ions or p-type ions into the conductive gate to form n-type or p-type gate. The damascene mask is removed and then a lightly doped ion implant is conducted to form lightly doped source/drain regions. Finally, spacers are formed on the sidewalls of the gates and the offset spacers and then a heavily doped ion implant is carried out to form the heavily doped source/drain regions.

According to the method of manufacturing the self-align offset gate, problems caused by narrow gate width can be resolved. The method of first forming a gate opening above a substrate and then forming a conductive gate flush inside the opening is a trench technique capable of overcoming conventional narrow line problem in gate fabrication. Hence, the level of integration for transistors is increased. Another advantage is that the offset spacers will not increase gate line width so that area wastage is prevented.

In addition, since the gate is formed flush into the gate opening of the damascene mask by a damascene process, p-type gate and n-type gate profiles are fixed when the gate opening is formed. The gate openings are formed by etching with the same etching conditions as etching the damascene mask. Since the same etching process is used to form both the gate openings of the p-type gate and the n-type gate, the gate profile is not influenced by the doping states.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 5 are schematic cross-sectional views showing the progression of steps for manufacturing the gate and source/drain terminals of a conventional device; and

FIGS. 6 through 11 are schematic cross-sectional views showing the progression of steps for manufacturing a metal-oxide-semiconductor device according to one preferred embodiment of this invention.

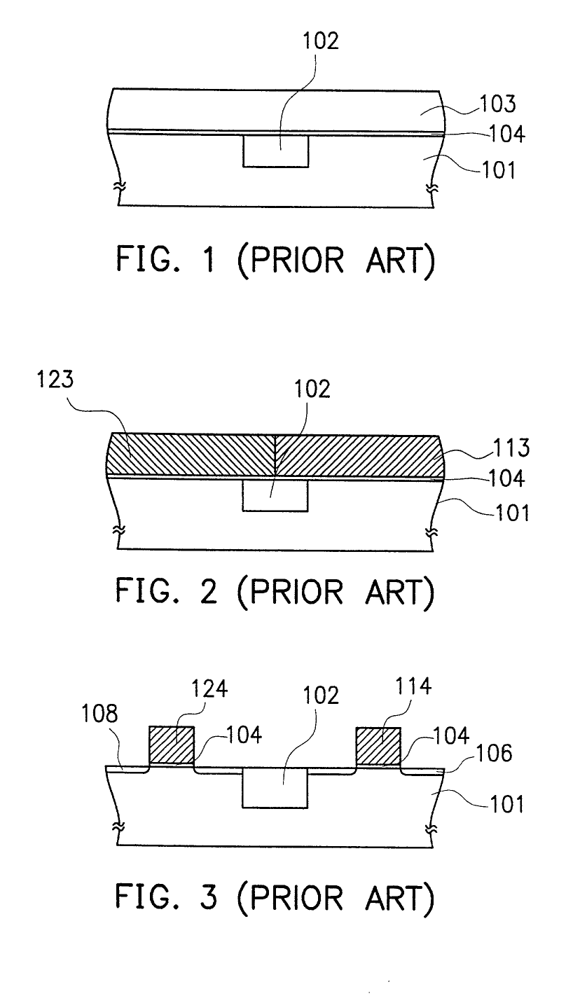

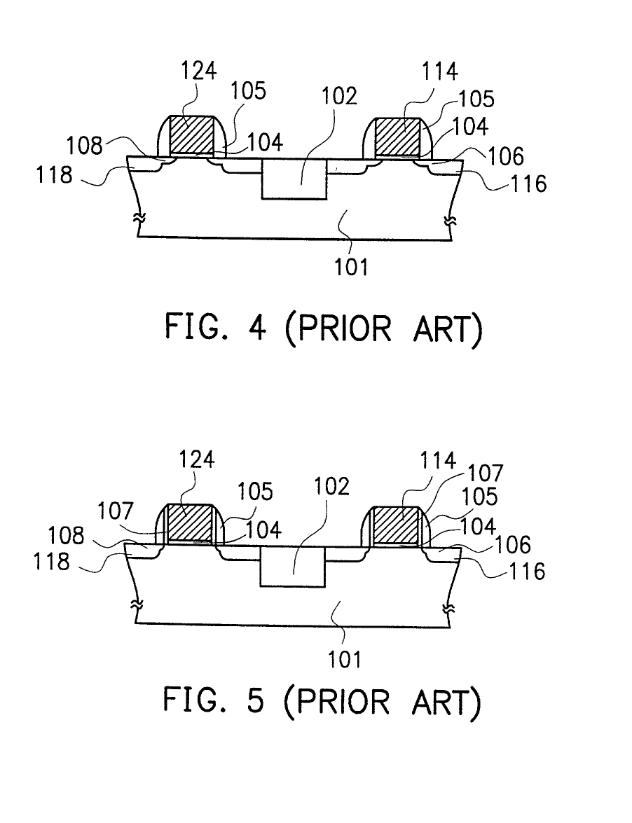

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

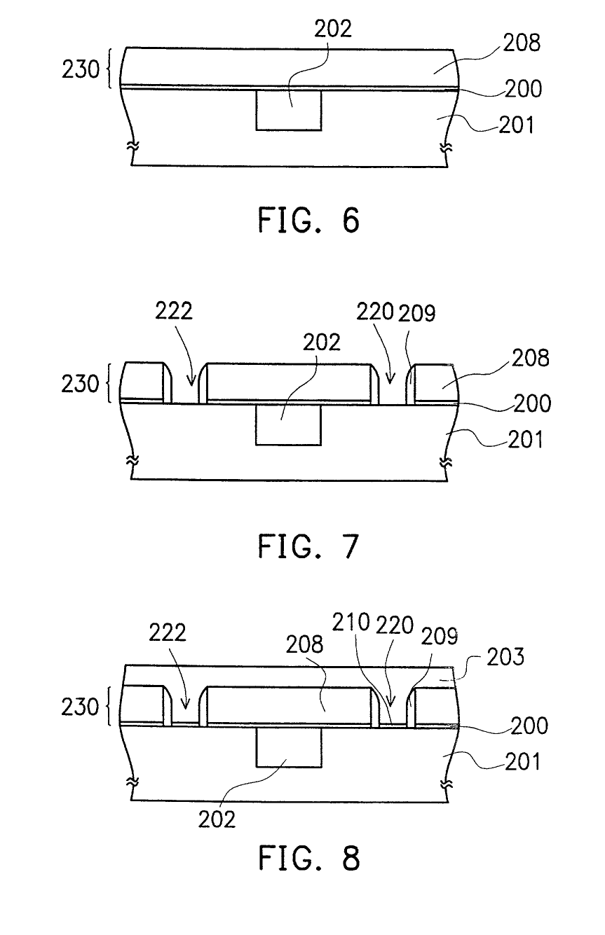

FIGS. 6 through 11 are schematic cross-sectional views showing the progression of steps for manufacturing a metal-oxide-semiconductor device according to one preferred embodiment of this invention. As shown in FIG. 6, a substrate 201 having an isolation structure 202 is provided. The isolation structure 202 can be a shallow trench isolation (STI) structure, for example. A damascene mask 230 is formed over the substrate 201. The damascene mask 203 is composed, for example, of an oxide layer 200 and a silicon nitride layer 208. The oxide layer 200 having a thickness of between 300 Å to 600 Å, and preferably a thickness of 500 Å, can be a silicon oxide layer formed, for example, by chemical vapor deposition. The silicon nitride layer 208 has a thickness roughly identical to the subsequently formed gate. The silicon nitride layer 208 is formed, for example, by chemical vapor deposition. As shown in FIG. 7, conventional photolithographic and etching processes are conducted in sequence. A patterned photoresist layer (not shown) is formed over the damascene mask 230 serving as a mask. The exposed damascene mask 230 is dry etched until the substrate 201 is exposed, thereby forming gate openings 220 and 222 in the damascene mask 230. Offset spacers 209 are formed on the sidewalls of the gate openings 220 and 222. Material constituting the offset spacers 209 includes silicon oxide and silicon nitride. The offset spacers 209 are formed by depositing silicon oxide or silicon nitride in chemical vapor deposition and then etching back the deposited material. The offset spacers 209 preferably have a base width of about 10 Å to 300 Å.

As shown in FIG. 8, a gate oxide layer 210 is formed over the exposed substrate 201 at the bottom of the openings 220 and 222. The gate oxide layer 210 is formed, for example, by thermal oxidation. A conductive layer 203 is formed over the damascene mask 230 and the gate oxide layer 210. Material constituting the conductive layer 203 includes polysilicon, tungsten, tungsten nitride, titanium silicide or polysilicon/silicide.

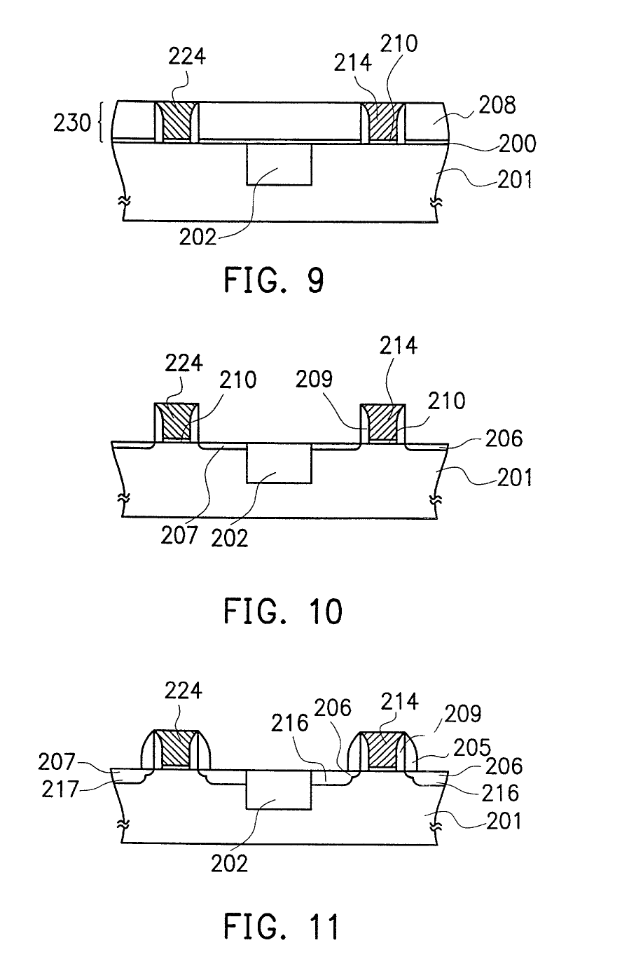

As shown in FIG. 9, the conductive layer 203 over the damascene mask 230 is removed such that only the conductive layer 203 within the gate openings 220 and 222 is retained. The conductive layer 203 is removed, for example, by chemical-mechanical polishing. An n-type ion doping process is carried out to form an n-type gate 214 in the conductive layer 203 inside the gate opening 220. The n-type gate 214 is formed by depositing a photoresist layer (not shown) over the silicon nitride layer 208 and then patterning the photoresist layer. Using the patterned photoresist layer as mask layer, an n-type ion implant is carried out to turn the conductive layer 203 inside the gate opening 220 into the n-type gate 214. Finally, the photoresist layer is removed. Similarly, a p-type ion doping process is carried out to form a p-type gate 224 in the conductive layer 203 inside the gate opening 222. The p-type gate 224 is formed by depositing a photoresist layer (not shown) over the silicon nitride layer 208 and then patterning the photoresist layer. Using the patterned photoresist layer as mask layer, a p-type ion implant is carried out to turn the conductive layer 203 inside the gate opening 222 into the n-type gate 224. Finally, the photoresist layer is removed.

As shown in FIG. 10, the silicon nitride layer 208 and the oxide layer 200 are removed to expose the substrate 201, the n-type gate 214, the p-type gate 224. The damascene mask 230 (including the silicon nitride layer 208 and the oxide layer 200) is removed, for example, by wet etching or dry etching. Ion implant using low dose n-type or p-type ions are conducted to form lightly doped source/drain regions 206 and 207 in the substrate 201 on each side of the n-type gate 214 and the p-type gate 224.

As shown in FIG. 11, a spacer material layer (not shown) is formed over the substrate 201. The spacer material layer is formed, for example, by low-pressure chemical vapor deposition (LPCVD). Thereafter, the spacer material layer is etched to remove excess material and form gate spacers 205 on the offset sidewalls 210 of the n-type gate 214 and the p-type gate 224. Each spacer 205 is in contact with the offset sidewall 210. In the subsequent steps, depending on individual design, another ion implant is conducted selectively forming heavily doped source/drain regions 216 and 217 in the substrate 201 on each side of the gate spacers 205. The heavily doped source/drain regions 216 and 217 together with the lightly doped source/drain regions 206 and 207 form the source/drain regions of a MOS transistor.

According to the aforementioned method, the self-align offset spacer gate structure of this invention is formed. By adding or subtracting some steps, the method can also be applied to form other types of gate structure as well.

In conclusion, the invention includes the following advantages:

1. In this invention, the gate is formed inside a gate opening and thus the gate width is not limited by the yellow light used in a photolithographic station. Hence, a gate having a finer width can be produced.

2. The offset sidewalls are hidden under the gate. Hence, the original gate width can be retained while parasitic capacitance problem can be avoided.

3. The self-align offset gate is formed inside a damascene mask using a damascene process followed by removing the damascene mask. Therefore, profile of the p-type gate and the n-type gate is fixed when the gate opening is formed. In addition, the gate opening is formed under the same etching conditions as the etching the damascene mask. Hence, profile of the gate can be maintained despite having a variety of doping states for the gates.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a self-align offset gate structure, comprising the steps of:
forming a damascene mask over a substrate;
forming a plurality of gate openings in the damascene mask, wherein the gate openings expose a portion of the substrate;
forming offset spacers on the sidewalls of the gate openings;
forming a plurality of doped gates inside the gate openings;
removing the damascene mask; and
forming gate spacers on the offset sidewalls of the doped gates.

2. The method of claim 1, wherein the step of forming the damascene mask includes the sub-steps of:
forming a silicon oxide layer over the substrate; and
forming a silicon nitride layer over the silicon oxide layer.

3. The method of claim 1, wherein material constituting the offset spacers is either an oxide or a silicon nitride.

4. The method of claim 1, wherein the bottom portion of the offset spacers has a width between about 10 Å to 300 Å.

5. The method of claim 1, wherein the step of forming the doped gates includes the sub-steps of:
forming a plurality of gates inside the gate openings; and
implanting n-type and implanting p-type ions into the gates selectively.

6. The method of claim 1, wherein the step of forming the gates inside the gate openings further includes the sub-steps of:
forming a conductive layer over the substrate to fill the gate opening; and
removing the conductive layer above the damascene mask.

7. The method of claim 6, wherein material constituting the conductive layer is selected from a group consisting of polysilicon, tungsten, tungsten nitride, titanium silicide and polysilicon/silicide.

8. The method of claim 7, wherein the step of removing the conductive layer above the damascene mask includes chemical-mechanical polishing.

9. A self-align offset gate in a metal-oxide-semiconductor structure, comprising:
a gate above a substrate, wherein the gate has a profile with upper portion wider than the lower portion;
a gate spacer above the substrate, wherein the upper portion of the spacer joins with the upper section of the gate;
an offset sidewall located between the gate and the gate spacer, wherein the interface between offset sidewall and the gate spacer is a plane; and
a source/drain region in the substrate on each side of the gate, wherein the source/drain region is further composed of a lightly doped source/drain region and a heavily doped source/drain region.

10. The structure of claim 9, wherein material constituting the offset spacer is either an oxide or a silicon nitride.

11. The structure of claim 9, wherein the bottom portion of the offset spacers has a width between about 10 Å to 300 Å.

12. The structure of claim 9, wherein material constituting the gate is selected from a group consisting of polysilicon, tungsten, tungsten nitride, titanium silicide and polysilicon/silicide.

13. The structure of claim 9, wherein material constituting the gate spacer includes silicon nitride.

14. A method of manufacturing a self-align offset gate in a metal-oxide-semiconductor device, comprising the steps of:
forming a damascene mask over a substrate;
forming a plurality of gate openings in the damascene mask, wherein the gate openings expose a portion of the substrate;
forming offset spacers on the sidewalls of the gate openings;
forming a plurality of doped gates inside the gate openings;
removing the damascene mask;
forming a lightly doped source/drain region in the substrate on each side of offset spacers;
forming gate spacers on the offset sidewalls of the doped gates; and
forming a heavily doped source/drain region in the substrate on each side of the doped gate spacers.

15. The method of claim 14, wherein the step of forming the damascene mask includes the sub-steps of:
forming a silicon oxide layer over the substrate; and
forming a silicon nitride layer over the silicon oxide layer.

16. The method of claim 14, wherein material constituting the offset spacers is either an oxide or a silicon nitride.

17. The method of claim 14, wherein the bottom portion of the offset spacers has a width between about 10 Å to 300 Å.

18. The method of claim 14, wherein the step of forming the doped gates includes the sub-steps of:
forming a plurality of gates inside the gate openings; and
implanting n-type and implanting p-type ions into the gates selectively.

19. The method of claim 18, wherein the step of forming the gates inside the gate openings further includes the sub-steps of:
forming a conductive layer over the substrate to fill the gate opening; and
removing the conductive layer above the damascene mask.

20. The method of claim 19, wherein material constituting the conductive layer is selected from a group consisting of polysilicon, tungsten, tungsten nitride, titanium silicide and polysilicon/silicide.

21. The method of claim 19, wherein the step of removing the conductive layer above the damascene mask includes chemical-mechanical polishing.

22. The method of claim 14, wherein the step of forming the lightly doped source/drain region includes performing an ion implant.

23. The method of claim 14, wherein the step of forming the heavily doped source/drain region includes performing an ion implant.
